(19) United States
(12) Patent Application Publication
(10) Pub. No.: US 2026/0169387 A1
(43) Pub. Date: Jun. 18, 2026

(54) SUBSTRATE PROCESSING DEVICE

(71) Applicant: SEMES CO., LTD., Cheonan-si (KR)

(72) Inventors: Ji Young CHOI, Hwaseong-si (KR); Dong Woon PARK, Seoul (KR); Ki Hoon LIM, Bucheon-si (KR); Byoung Doo CHOI, Cheonan-si (KR)

(21) Appl. No.: 19/386,303

(22) Filed: Nov. 12, 2025

(30) Foreign Application Priority Data
Dec. 18, 2024 (KR) 10-2024-0189904

(51) Int. Cl. G03F 7/20; G03F 7/40; H01L 21/027; H01L 21/687

(52) U.S. Cl. CPC G03F 7/2004; G03F 7/40; H10P 72/7624; H10P 76/2041

(57) ABSTRACT

A substrate processing device includes a plurality of processing chambers in which substrates are disposed, respectively, and an ultraviolet (UV) light source disposed between the plurality of processing chambers and irradiating the respective substrates in the plurality of processing chambers with UV light.

### CROSS-REFERENCE TO RELATED APPLICATIONS

This application claims benefit of priority to Korean Patent Application No. 10-2024-0189904 filed on Dec. 18, 2024 in the Korean Intellectual Property Office, the disclosure of which is incorporated herein by reference in its entirety.

### BACKGROUND

### 1. Field

The present disclosure relates to a substrate processing device for processing a substrate.

### 2. Description of Related Art

Semiconductor manufacturing processes or manufacturing processes for liquid crystal displays (LCDs) involve a plurality of thin film formation processes. These thin film formation processes primarily utilize photolithography, which includes an application operation of applying a photosensitive material, photoresist, and an exposure operation of forming a predetermined pattern.

During the exposure operation, it is essential to thoroughly clean an exposure interface to ensure that there are no foreign substances in order to form a very precise pattern.

In the manufacturing process for semiconductors and thin film transistor (TFT) LCDs using semiconductor technology, cleaning processes include wet cleaning using pure water and optical cleaning using excimer ultraviolet (EUV).

For example, in a photolithography process using a photosensitive organic film, carbon-based organic films may be removed using EUV.

Meanwhile, while the light (ultraviolet rays) from a UV lamp radiates 360 degrees, there is a limitation in that only light radiating in one direction is actually used inside processing chambers.

### RELATED ART DOCUMENT

### Patent Document

(Patent Document 1) Korean Application Publication No. 10-2001-0029076

### SUMMARY

An aspect of the present disclosure is to provide a substrate processing device capable of maximizing the use of ultraviolet rays emitted from a ultraviolet (UV) lamp.

According to an aspect of the present disclosure, a substrate processing device includes: a plurality of processing chambers in which substrates are disposed, respectively; and an ultraviolet (UV) light source disposed between the plurality of processing chambers and irradiating the respective substrates in the plurality of processing chambers with UV light.

The substrate processing device may further include: a lamp housing in which the UV light source is disposed, wherein the plurality of the processing chambers include two processing chambers arranged to face each other and connected by the lamp housing.

The substrate of each of the two processing chambers may be arranged such that an application surface faces the UV light source.

The substrate of one of the two processing chambers may be arranged such that an application surface faces the UV light source, and the substrate of the other processing chamber may be arranged such that a non-application surface faces the UV light source.

The substrate processing device may further include: a lamp housing in which the UV light source may be disposed, wherein the plurality of processing chambers include four processing chambers arranged one at each of upper, lower, left, and right sides of the lamp housing and connected by the lamp housing, and two of the four processing chambers are arranged to face each other, and the other two processing chambers are arranged to face each other.

The substrate of each of the four processing chambers may be arranged such that an application surface faces the UV light source.

The substrates in some processing chambers among the four processing chambers may be arranged such that application surfaces face the UV light source, and the substrates in the other processing chambers may be arranged such that non-application surfaces face the UV light source.

The UV light source may include a plurality of UV lamps, and the plurality of UV lamps irradiate UV light with different wavelengths.

The plurality of UV lamps may include: a first UV lamp irradiating UV light with a wavelength of 170 nm to 190 nm; and a second UV lamp irradiating UV light with a wavelength of 300 nm to 450 nm.

The substrate processing device may further include: a lamp housing connecting the plurality of processing chambers and including the UV light source disposed in the lamp housing; and a transparent window installed between each of the plurality of processing chambers and the lamp housing.

According to another aspect of the present disclosure, a substrate processing device includes: two processing chambers arranged to face each other and each having a substrate disposed in each of the two processing chambers; a UV light source disposed between the two processing chambers and irradiating the substrates in the two processing chambers with UV light; a lamp housing including the UV light source; two transparent windows installed between the two processing chambers and the lamp housing; and two support units installed inside the two processing chambers and supporting the substrates.

According to another aspect of the present disclosure, a substrate processing device includes: four processing chambers, each of two processing chambers being disposed to face the other, each having a substrate disposed therein; a UV light source disposed between the four processing chambers and irradiating the substrates in the four processing chambers with UV light; a lamp housing in which the UV light source may be disposed; four transparent windows installed between the four processing chambers and the lamp housing; and four support units installed inside the four processing chambers and supporting the substrates.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a diagram illustrating a substrate processing device according to the related art;

FIG. 2 is a diagram illustrating a substrate processing device according to a first embodiment of the present disclosure;

FIG. 3 is a diagram illustrating a substrate processing device according to a second embodiment of the present disclosure;

FIG. 4 is a diagram illustrating a substrate processing device according to a third embodiment of the present disclosure;

FIG. 5 is a diagram illustrating a substrate processing device according to a fourth embodiment of the present disclosure;

FIG. 6 is a diagram illustrating a substrate processing device according to a fifth embodiment of the present disclosure; and

FIG. 7 is a diagram illustrating a substrate processing device according to a sixth embodiment of the present disclosure.

### DETAILED DESCRIPTION

Hereinafter, embodiments will be described in detail with reference to the accompanying drawings such that they may be easily practiced by those skilled in the art to which the present disclosure pertains. In describing the present disclosure, if a detailed explanation for a related known function or construction is considered to unnecessarily divert the gist of the present disclosure, such explanation will be omitted but would be understood by those skilled in the art. Also, similar reference numerals are used for the similar parts throughout the specification. In this disclosure, terms., such as “above,” “upper portion,” “upper surface,” “below,” “lower portion,” “lower surface,” “lateral surface,” and the like, are determined based on the drawings, and in actuality, the terms may be changed according to a direction in which a device or an element is disposed.

It will be understood that when an element is referred to as being “connected to” another element, it may be directly connected to the other element or intervening elements may also be present. In contrast, when an element is referred to as being “directly connected to” another element, no intervening elements are present. In addition, unless explicitly described to the contrary, the word “comprise” and variations, such as “comprises” or “comprising,” will be understood to imply the inclusion of stated elements but not the exclusion of any other elements.

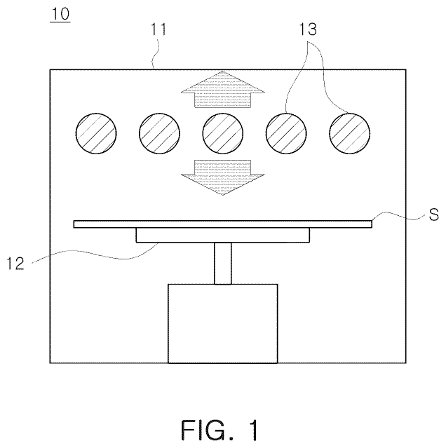

FIG. 1 is a diagram illustrating a substrate processing device according to the related art.

Referring to FIG. 1, a substrate processing device 10 according to the related art includes a baking chamber 11 for performing optical cleaning on a substrate S.

In the baking chamber 11, the substrate S is supported by a support unit 12 and irradiated with ultraviolet light from an ultraviolet (UV) lamp 13, thereby removing organic materials on the substrate S by UV light.

The UV lamp has a structure of radiating light (UV light) in a 360-degree direction, i.e., in all directions.

However, the substrate processing device 10 according to the related art only uses UV light radiated in one direction within the baking chamber 11.

That is, the UV lamp 13 is disposed above the substrate S within the baking chamber 11, so only UV light radiated in a downward direction toward the substrate S is used.

If only UV light radiated in one direction from the UV lamp 13 is used, UV light radiated in other directions from the UV lamp 13 cannot be used, resulting in inefficiency in terms of productivity.

Furthermore, since the UV lamp 13 irradiating UV light is expensive, the use of only UV light radiated in one direction also may result in cost waste.

To overcome the limitations of the related art, the present disclosure includes various embodiments as follows.

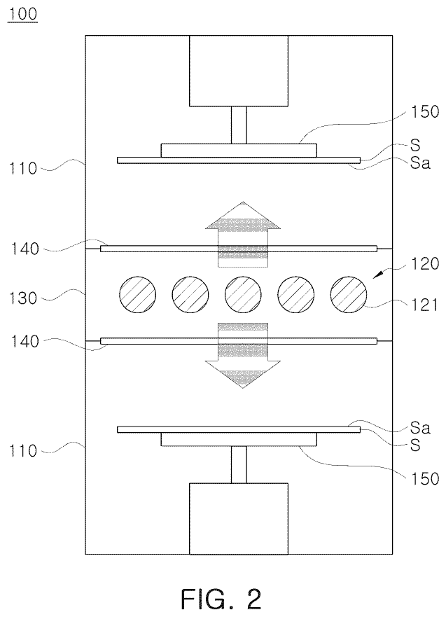

FIGS. 2 to 7 illustrate substrate processing devices according to various embodiments of the present disclosure.

Referring to the drawings, a substrate processing device 100 according to the present disclosure includes a plurality of processing chambers 110 and a UV light source 120.

Each of the plurality of processing chambers 110 has a processing space formed therein, in which a substrate S is disposed.

A support unit 150 supporting the substrate S is installed within each of the plurality of processing chambers 110.

The support unit 150 is not limited to the present disclosure, and any conventional support chuck capable of firmly and stably supporting the substrate S may be utilized.

Furthermore, the UV light source 120 is disposed between the plurality of processing chambers 110 to irradiate UV light onto the substrate S within each of the plurality of processing chambers 110.

In a photolithography process using a photosensitive organic film, carbon-based organic materials remain on the substrate S after wet cleaning, inevitably requiring optical cleaning for complete cleaning.

UV light from the UV light source remove the carbon-based organic film, which is an organic contaminant, from the substrate S. That is, UV light converts oxygen into reactive oxygen and ozone, which decompose and remove the organic contaminant attached to the surface of the substrate S. In other words, the carbon-based organic film reacts with the oxygen and ozone ions decomposed by UV light so as to be changed into CO, CO₂, or H₂O and removed.

This UV light source 120 is disposed within a lamp housing 130. Although not illustrated in the drawing, nitrogen may flow into and out of the lamp housing 130 as an atmospheric gas.

Furthermore, a transparent window 140 may be installed between each of the plurality of processing chambers 110 and the lamp housing 130, thereby partitioning the plurality of processing chambers 110 from the lamp housing 130.

The transparent window 140 may be formed of quartz glass with excellent light transmittance.

As described above, in the present disclosure, the UV light source 120 is disposed between the plurality of processing chambers 110 and irradiating each substrate S with UV light in each of the plurality of processing chambers 110, and thus, UV light radiated from the UV light source 120 may be efficiently utilized without waste.

Furthermore, the present disclosure may improve productivity by simultaneously processing a plurality of substrates S and is cost-effective by simultaneously using the expensive UV light source 120 on the plurality of substrates S.

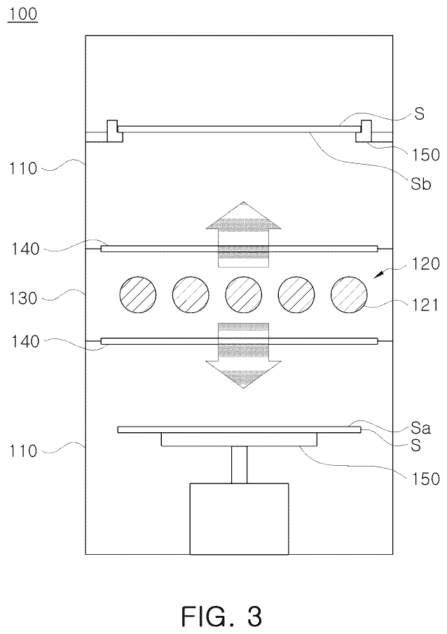

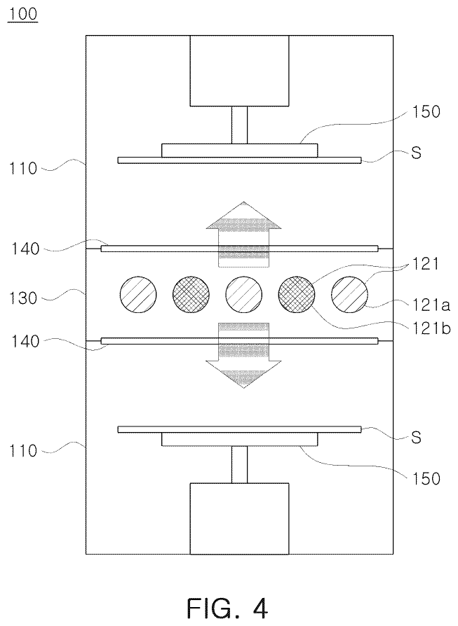

Specifically, according to a first embodiment of the present disclosure illustrated in FIG. 2, a second embodiment of the present disclosure illustrated in FIG. 3, and a third embodiment of the present disclosure illustrated in FIG. 4, the plurality of processing chambers 110 may include two processing chambers 110.

The two processing chambers 110 may be arranged to face each other and connected by the lamp housing 130.

Although the two processing chambers 110 are arranged above and below the lamp housing 130 in the drawing, the present disclosure is not limited to this arrangement. That is, although not illustrated in the drawing, the two processing chambers 110 may be arranged on the left and right of the lamp housing 130, respectively.

Furthermore, the present disclosure may include two transparent windows 140 and two support units 150.

The two transparent windows 140 are installed between the two processing chambers 110 and the lamp housing 130. That is, one transparent window 140 may be disposed between each of the two processing chambers 110 and the lamp housing 130.

Two support units 150 are installed inside the two processing chambers 110 and support the substrate S. That is, one support unit 150 is disposed inside each of the two processing chambers 110, and each support unit 150 may support one substrate S.

As described above, in the present disclosure, the UV light source 120 is disposed between the two processing chambers 110 and irradiating the substrate S in each of the two processing chambers 110 with UV light. This effectively utilizes the UV light radiated from the expensive UV light source 120, which is efficient in terms of production and cost.

More specifically, according to the first embodiment of the present disclosure illustrated in FIG. 2, the substrates S in each of the two processing chambers 110 may be arranged such that an application surface Sa faces the UV light source 120.

For example, photoresist may be applied to one surface of the substrate S. The substrate S may be arranged such that the application surface Sa to which the photoresist is applied faces the UV light source 120.

That is, the two support units 150 support the substrates S within the two processing chambers 110, and the application surfaces Sa of the two substrates S may be configured to face the UV light source 120.

As described above, the two substrates S in the two processing chambers 110 are arranged such that the application surface Sa faces the UV light source 120, thereby simultaneously removing the carbon-based organic film, which is an organic contaminant, by the UV light irradiated from the UV light source 120.

Unlike the above, according to the second embodiment of the present disclosure illustrated in FIG. 3, the substrate S in one of the two processing chambers 110 is arranged such that the application surface Sa faces the UV light source 120, while the substrate S in the other processing chamber 110 is arranged such that a non-application surface Sb faces the UV light source 120. This structure may be used to clean the backside of the substrate S, i.e., the non-application surface Sb.

For example, a photoresist may be applied to one surface of the substrate S. The substrate S in one of the two processing chambers 110 may be arranged such that the application surface Sa to which the photoresist is applied faces the UV light source 120. Furthermore, the substrate S in the other of the two processing chambers 110 may be arranged such that the non-application surface Sb to which the photoresist is not applied faces the UV light source 120.

That is, two support units 150 support the substrates S inside the two processing chambers 110, and the application surface Sa of one of the two substrates S may be configured to face the UV light source 120, and the non-application surface Sb of the other of the two substrates S may be configured to face the UV light source 120.

As described above, the substrate S in one of the two processing chambers 110 is arranged such that the application surface Sa faces the UV light source 120, and thus, the carbon-based organic film may be removed by UV light irradiated from the UV light source 120. In addition, the substrate S in the other of the two processing chambers 110 is arranged such that the application surface Sa does not face the UV light source 120 and the non-application surface Sb faces the UV light source 120, so that a general cleaning process (removal of foreign substances) may be performed on the non-application surface Sb by the UV light irradiated from the UV light source 120.

Meanwhile, according to the third embodiment of the present disclosure illustrated in FIG. 4, the UV light source 120 may include a plurality of UV lamps 121, which may irradiate UV light with different wavelengths. However, the plurality of UV lamps 121 do not operate simultaneously but rather operate according to respective wavelengths thereof. That is, when a first UV lamp 121a to be described below operates, a second UV lamp 121b may not operate, or when the second UV lamp 121b operates, the first UV lamp 121a may not operate.

Specifically, the plurality of UV lamps 121 may include the first UV lamp 121a and the second UV lamp 121b.

The first UV lamp 121a irradiates UV light with a wavelength of 170 nm to 190 nm.

In this manner, the first UV lamp 121a irradiates short-wavelength UV light with a wavelength of 170 to 190 nm. As the short-wavelength UV light converts oxygen into reactive oxygen and ozone, organic contaminants attached to the surface of the substrate S are decomposed and removed.

In other words, the carbon-based organic film reacts with the oxygen ions and ozone ions decomposed by the short-wavelength UV light so as to be changed into CO₂ or H₂O and removed. Consequently, some of the organic substances present on the substrate S may be removed.

Furthermore, the first UV lamp 121a also serves to compensate for the lack of extreme UV (EUV) in photoresist films containing inorganic substances. In situations in which EUV is insufficient, irradiation by the first UV lamp 121a blasts away organic substances contained in the inorganic film and enhances cross-linking reactions, thereby enhancing the etching resistance and stability of the photoresist.

The second UV lamp 121b irradiates UV light with a wavelength of 300 nm to 450 nm.

The second UV lamp 121b irradiates long-wavelength UV light with a wavelength of 300 nm to 450 nm. The long-wavelength UV light reacts with a photoreactive agent included in the photoresist, causing a cross-linking reaction within the photoresist. The cross-linking reaction hardens the photoresist, thereby enhancing the etching resistance of the photoresist.

The second UV lamp 121b also serves to compensate for insufficient photoexposure light intensity. In situations in which the photoexposure light intensity is insufficient, the long-wavelength UV light from the second UV lamp 121b enhances the cross-linking reaction in the photoresist, thereby enhancing the etching resistance and stability of the photoresist.

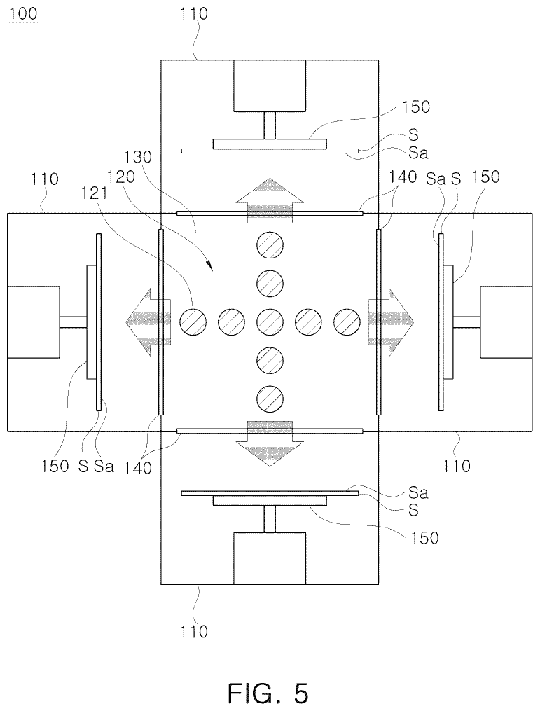

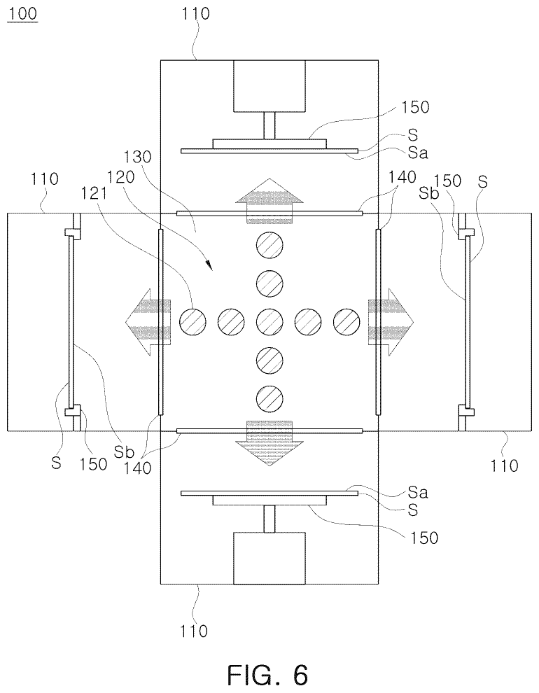

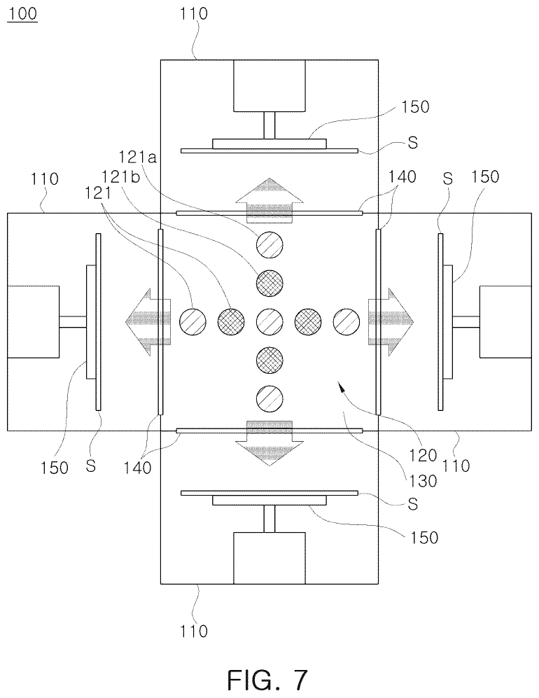

Meanwhile, according to a fourth embodiment of the present disclosure illustrated in FIG. 5, a fifth embodiment of the present disclosure illustrated in FIG. 6, and a sixth embodiment of the present disclosure illustrated in FIG. 7, the plurality of processing chambers 110 may include four processing chambers 110.

The four processing chambers 110 may be arranged such that two processing chambers 110 face each other and the other two processing chambers 110 face each other.

In addition, the four processing chambers 110 may be connected by the lamp housing 130.

Furthermore, the present disclosure may include four transparent windows 140 and four support units 150.

The four transparent windows 140 are installed between the four processing chambers 110 and the lamp housing 130. That is, one transparent window 140 may be disposed between each of the four processing chambers 110 and the lamp housing 130.

The four support units 150 are installed within the four processing chambers 110 and support the substrates S, respectively. That is, one support unit 150 is disposed within each of the four processing chambers 110, and each support unit 150 may support one substrate S.

As described above, in the present disclosure, the UV light source 120 is disposed between the four processing chambers 110 and irradiate the substrate S within each of the four processing chambers 110 with UV light, and thus, the UV light emitted from the expensive UV light source 120 may be efficiently utilized, which is efficient in terms of production and cost.

More specifically, according to the fourth embodiment of the present disclosure illustrated in FIG. 5, the substrate S in each of the four processing chambers 110 may be arranged such that the application surface Sa faces the UV light source 120.

For example, photoresist may be applied to one surface of the substrates S, and the substrate S may be arranged such that the application surface Sa to which the photoresist is applied faces the UV light source 120.

That is, the four support units 150 support the substrates S within the four processing chambers 110, respectively, and the application surfaces Sa of each of the four substrates S may be configured to face the UV light source 120.

As described above, the four substrates S in the four processing chambers 110 are arranged such that the application surface Sa faces the UV light source 120, and thus, the carbon-based organic film, which is an organic contaminant, may be removed simultaneously by the UV light irradiated from the UV light source 120.

Unlike the above, according to the fifth embodiment of the present disclosure illustrated in FIG. 6, the substrates S in some of the four processing chambers 110 are arranged such that the application surface Sa faces the UV light source 120, while the substrates S in the other processing chambers 110 are arranged such that the non-application surface Sb faces the UV light source 120. This structure may be used to clean the backside of the substrates S, i.e., the non-application surface Sb.

For example, photoresist may be applied to one surface of the substrate S. The substrates S of one group of the processing chambers 110 among the four processing chambers 110 may be arranged such that the application surface Sa to which the photoresist is applied faces the UV light source 120. In addition, the substrates S of the other group of the processing chambers 110 among the four processing chambers 110 may be arranged such that the non-application surface Sb to which the photoresist is not applied faces the UV light source 120.

That is, the four support units 150 support the substrates S within the four processing chambers 110. The application surfaces Sa of one group of the four substrates S may be configured to face the UV light source 120, and the non-application surfaces Sb of the other group of the four substrates S may be configured to face the UV light source 120.

As described above, the substrates S of one group of the four processing chambers 110 are arranged such that the application surfaces Sa face the UV light source 120, thereby removing the carbon-based organic film by the UV light irradiated from the UV light source 120. In addition, the substrates S of the other group of processing chambers 110 are arranged such that the application surfaces Sa do not face the UV light source 120 but the non-application surfaces Sb face the UV light source 120, and thus, a general cleaning process (removal of foreign substances) may be performed on the non-application surfaces Sb by UV light irradiated from the UV light source 120.

Meanwhile, according to the sixth embodiment of the present disclosure illustrated in FIG. 7, the UV light source 120 may include a plurality of UV lamps 121, which may irradiate UV light with different wavelengths. However, the plurality of UV lamps 121 do not operate simultaneously, but rather operate according to respective wavelengths thereof. That is, when the first UV lamp 121a to be described below operates, the second UV lamp 121b may not operate, or when the second UV lamp 121b operates, the first UV lamp 121a may not operate.

Specifically, the plurality of UV lamps 121 may include the first UV lamp 121a and the second UV lamp 121b.

The first UV lamp 121a irradiates UV light with a wavelength of 170 nm to 190 nm.

In this manner, the first UV lamp 121a irradiates short-wavelength UV light with a wavelength of 170 nm to 190 nm. As the short-wavelength UV light converts oxygen into reactive oxygen and ozone, organic contaminants attached to the surface of the substrate S are decomposed and removed.

In other words, the carbon-based organic film reacts with oxygen ions and ozone ions, which are decomposed by short-wavelength UV light so as to be changed into CO, CO₂, or H₂O and removed. Accordingly, some of the organic substances present on the substrate S may be removed.

Furthermore, the first UV lamp 121a also serves to compensate for the lack of EUV in photoresist films containing inorganic substances. In situations in which EUV is insufficient, irradiation by the first UV lamp 121a blasts away organic substances included in the inorganic film and enhances crosslinking reactions, thereby enhancing the etching resistance and stability of the photoresist.

The second UV lamp 121b irradiates UV light with a wavelength of 300 nm to 450 nm.

In this manner, the second UV lamp 121b irradiates long-wavelength UV light with a wavelength of 300 nm to 450 nm. The long-wavelength UV light reacts with a photoreactive agent contained in the photoresist, causing a crosslinking reaction within the photoresist. The crosslinking reaction hardens the photoresist and enhances the etching resistance of the photoresist.

Furthermore, the second UV lamp 121b also serves to compensate for insufficient photoexposure light intensity. In situations in which the photoexposure light intensity is insufficient, the long-wavelength UV light from the second UV lamp 121b enhances the crosslinking reaction in the photoresist, thereby enhancing the etching resistance and stability of the photoresist.

According to an embodiment of the present disclosure, in the substrate processing device, since the UV light source is disposed between a plurality of processing chambers and irradiates the substrates in the plurality of processing chambers with UV light, thereby efficiently utilizing the UV light radiated from the UV light source without waste.

Furthermore, in the present disclosure, since substrate processing is performed on a plurality of substrates simultaneously, the productivity may be improved, and the use of an expensive UV light source in a plurality of substrates simultaneously is efficient in terms of cost.

While embodiments have been illustrated and described above, it will be apparent to those skilled in the art that modifications and variations could be made without departing from the scope of the present disclosure as defined by the appended claims.

What is claimed is:

1. A substrate processing device comprising:
a plurality of processing chambers in which substrates are disposed, respectively; and
an ultraviolet (UV) light source disposed between the plurality of processing chambers and irradiating the respective substrates in the plurality of processing chambers with UV light.

2. The substrate processing device of claim 1, further comprising:
a lamp housing in which the UV light source is disposed,
wherein the plurality of the processing chambers include two processing chambers arranged to face each other and connected by the lamp housing.

3. The substrate processing device of claim 2, wherein the substrate of each of the two processing chambers is arranged such that an application surface faces the UV light source.

4. The substrate processing device of claim 2, wherein the substrate of one of the two processing chambers is arranged such that an application surface faces the UV light source, and the substrate of the other processing chamber is arranged such that a non-application surface faces the UV light source.

5. The substrate processing device of claim 1, further comprising:
a lamp housing in which the UV light source is disposed,
wherein the plurality of processing chambers include four processing chambers arranged one at each of upper, lower, left, and right sides of the lamp housing and connected by the lamp housing, and two of the four processing chambers are arranged to face each other, and the other two processing chambers are arranged to face each other.

6. The substrate processing device of claim 5, wherein the substrate of each of the four processing chambers is arranged such that an application surface faces the UV light source.

7. The substrate processing device of claim 5, wherein the substrates in some processing chambers among the four processing chambers are arranged such that application surfaces face the UV light source, and the substrates in the other processing chambers are arranged such that non-application surfaces face the UV light source.

8. The substrate processing device of claim 1, wherein the UV light source includes a plurality of UV lamps, and the plurality of UV lamps irradiate UV light with different wavelengths.

9. The substrate processing device of claim 8, wherein
the plurality of UV lamps include:
a first UV lamp irradiating UV light with a wavelength of 170 nm to 190 nm; and
a second UV lamp irradiating UV light with a wavelength of 300 nm to 450 nm.

10. The substrate processing device of claim 1, further comprising:
a lamp housing connecting the plurality of processing chambers and including the UV light source disposed in the lamp housing; and
a transparent window installed between each of the plurality of processing chambers and the lamp housing.

11. A substrate processing device comprising:
two processing chambers arranged to face each other and each having a substrate disposed in each of the two processing chambers;
a UV light source disposed between the two processing chambers and irradiating the substrates in the two processing chambers with UV light;
a lamp housing including the UV light source;
two transparent windows installed between the two processing chambers and the lamp housing; and
two support units installed inside the two processing chambers and supporting the substrates.

12. The substrate processing device of claim 11, wherein the substrate of each of the two processing chambers is arranged such that an application surface faces the UV light source.

13. The substrate processing device of claim 11, wherein the substrate of one of the two processing chambers is arranged such that an application surface faces the UV light source, and the substrate of the other processing chamber is arranged such that a non-application surface faces the UV light source.

14. The substrate processing device of claim 11, wherein the UV light source includes a plurality of UV lamps, and the plurality of UV lamps irradiate UV light with different wavelengths.

15. The substrate processing device of claim 14, wherein
the plurality of UV lamps include:
a first UV lamp irradiating UV light with a wavelength of 170 nm to 190 nm; and
a second UV lamp irradiating UV light with a wavelength of 300 nm to 450 nm.

16. A substrate processing device comprising:
four processing chambers, each of two processing chambers being disposed to face the other, each having a substrate disposed therein;
a UV light source disposed between the four processing chambers and irradiating the substrates in the four processing chambers with UV light;
a lamp housing in which the UV light source is disposed;
four transparent windows installed between the four processing chambers and the lamp housing; and
four support units installed inside the four processing chambers and supporting the substrates.

17. The substrate processing device of claim 16, wherein the substrate of each of the four processing chambers are arranged such that an application surface faces the UV light source.

18. The substrate processing device of claim 16, wherein the substrates in some processing chambers among the four processing chambers are arranged such that application surfaces face the UV light source, and the substrates in the other processing chambers are arranged such that a non-application surfaces face the UV light source.

19. The substrate processing device of claim 16, wherein the UV light source includes a plurality of UV lamps, and the plurality of UV lamps irradiate UV light with different wavelengths.

20. The substrate processing device of claim 19, wherein
the plurality of UV lamps include:
a first UV lamp irradiating UV light with a wavelength of 170 nm to 190 nm; and
a second UV lamp irradiating UV light with a wavelength of 300 nm to 450 nm.
